(19) United States
(12) Patent Application Publication
(10) Pub. No.: US 2026/0150588 A1
(43) Pub. Date: May 28, 2026

(54) ARTICLES WITH METAL-DOPED SUPERCONDUCTING LAYER FORMED BY LASER-INDUCED METAL ION IMPLANTATION

(71) Applicant: CORNING INCORPORATED, CORNING, NY (US)

(72) Inventors: Qiumei Bian, Painted Post, NY (US); Jianwei Liu, Painted Post, NY (US)

(21) Appl. No.: 18/952,167

(22) Filed: Nov. 19, 2024

Related U.S. Application Data
(60) Provisional application No. 63/602,928, filed on Nov. 27, 2023.

(51) Int. Cl. H10N 60/85; H10N 60/01; H10N 60/20

(52) U.S. Cl. CPC H10N 60/857; H10N 60/0324; H10N 60/0436; H10N 60/0548; H10N 60/0576; H10N 60/0884; H10N 60/203

(57) ABSTRACT

A method for making a superconducting article, the method comprising: depositing a metal layer on a surface of a polycrystalline substrate; and focusing a pulsed laser beam on the metal layer to implant metal ions from the metal layer into the polycrystalline substrate, thereby forming a layered structure comprising: a polycrystalline substrate layer; and a metal-doped superconducting layer comprising a thickness tₛ greater than 10 μm and less than or equal to 50 μm, wherein the metal-doped superconducting layer comprises the metal ions.

### CROSS-REFERENCE TO RELATED APPLICATIONS

This application claims the benefit of priority of U.S. Provisional Application Ser. No. 63/602,928, filed on Nov. 27, 2023, the content of which is relied upon and incorporated herein by reference in its entirety.

### TECHNICAL FIELD

The present specification generally relates to superconducting articles and methods for making the same.

### BACKGROUND

Superconducting materials may be used in a variety of applications including, but not limited to, electric power transmission, electronic devices, quantum computing, communication technologies, magnetic resonance imaging (MRI) machines, and magnetically levitating trains. Thin-film superconductors have attracted attention due to their potential implementation in new devices and applications wherein the functionality and performance thereof depends on the confinement of superconducting properties within a surface layer of a bulk substrate. Thin-film superconductors have been fabricated using deposition techniques including atomic layer deposition, chemical vapor deposition, physical vapor deposition, and pulsed laser deposition. However, existing techniques for fabricating thin-film superconductors are limited in their ability to produce thin films exhibiting high-temperature superconductivity.

### SUMMARY

Accordingly, a need exists for a method for making articles having an enhanced superconducting layer. In particular, a need exists for a method for making articles having an enhanced superconducting layer that exhibits high-temperature superconductivity.

The present disclosure provides methods for making a superconducting article wherein a metal layer is deposited on a surface of a polycrystalline substrate and then subjected to a pulsed laser beam that causes metal ions from the metal layer to become implanted into the polycrystalline substrate. This process forms a layered structure comprising a polycrystalline substrate layer and a metal-doped superconducting layer.

In embodiments, the characteristics of the polycrystalline substrate, the characteristics of the metal layer, and the pulsed laser parameters are selected such that the resulting metal-doped superconducting layer has a thickness tₛ greater than 10 μm and less than or equal to 50 μm. Without wishing to be bound by theory, it is believed that the use of a polycrystalline substrate in combination with the pulsed laser parameters described herein allow for the fabrication of surface superconducting layers having unexpectedly high thicknesses, and that these unexpectedly high thicknesses contribute to enhanced superconductivity, i.e., a higher superconducting critical temperature T_{c}. In particular, again without wishing to be bound by theory, it is believed that the unexpectedly high thickness for the surface superconducting layers achieved by the methods described herein allows for the formation of metal-doped superconducting layers having a crystal structure, a composition, or both, that results in a higher superconducting critical temperature T_{c} than is achievable using conventional fabrication techniques.

According to a first aspect of the present disclosure, a method of making a superconducting article comprises depositing a metal layer on a surface of a polycrystalline substrate and focusing a pulsed laser beam on the metal layer to implant metal ions from the metal layer into the polycrystalline substrate, thereby forming a layered structure comprising: a polycrystalline substrate layer; and a metal-doped superconducting layer comprising a thickness tₛ greater than 10 μm and less than or equal to 50 μm, wherein the metal-doped superconducting layer comprises the metal ions.

A second aspect includes the first aspect, wherein the pulsed laser beam comprises: a pulse duration greater than or equal to 10 ns and less than or equal to 40 ns; a wavelength from 266 nm to 532 nm; a pulse energy greater than or equal to 10 μJ and less than or equal to 30 μJ; a repetition rate greater than or equal to 10 kHz and less than or equal to 100 kHz; and a scan speed greater than or equal to 50 mm/s and less than or equal to 1500 mm/s.

A third aspect includes the first aspect, wherein the pulsed laser beam comprises: a pulse duration greater than or equal to 5 ps and less than or equal to 20 ps; a wavelength from 532 nm to 1064 nm; a pulse energy greater than or equal to 20 μJ and less than or equal to 40 μJ; a repetition rate greater than or equal to 100 kHz and less than or equal to 400 kHz; and a scan speed greater than or equal to 500 mm/s and less than or equal to 3000 mm/s.

A fourth aspect includes the first aspect, wherein the pulsed laser beam comprises: a pulse duration greater than or equal to 300 fs and less than or equal to 1000 fs; a wavelength from 515 nm to 1030 nm; a pulse energy greater than or equal to 20 μJ and less than or equal to 40 μJ; a repetition rate greater than or equal to 100 kHz and less than or equal to 400 kHz; and a scan speed greater than or equal to 500 mm/s and less than or equal to 3000 mm/s.

A fifth aspect includes any one of the first through fourth aspects, wherein the metal layer is deposited via chemical vapor deposition; and the metal layer comprises a thickness tₘ greater than or equal to 2 nm and less than or equal to 3 nm.

A sixth aspect includes any one of the first through fourth aspects, wherein the metal layer is deposited via physical vapor deposition; and the metal layer comprises a thickness tₘ greater than or equal to 1 nm and less than or equal to 100 nm.

A seventh aspect includes any one of the first through fourth aspects, wherein the metal layer is deposited via chemical solution deposition; and the metal layer comprises a thickness tₘ greater than or equal to 10 nm and less than or equal to 3000 nm.

An eighth aspect includes any one of the first through seventh aspects, wherein the metal layer comprises a metal selected from the group consisting of copper, iron, nickel, cobalt, molybdenum, and bismuth.

A ninth aspect includes any one of the first through eighth aspects, wherein the polycrystalline substrate comprises a ceramic selected from the group consisting of: YBa₂Cu₃O_{7-α}, where 0≤α≤0.65; Pb_{10-β}Cu_{β}(PO₄)O, where 0.9≤β≤1.1; La_{2-γ}Sr_{γ}CuO₄, where 0≤γ≤0.2; La_{2-δ}Ba_{δ}CuO₄, where 0.05≤δ≤0.25; Bi₂Sr₂Ca₂Cu₃O_{10+ε}, where 0≤ε≤0.08; Pb₂Sr₂Y₁Cu₃O_{8+ζ}, where 0≤ζ≤1; LaFeAsO_{1-η}F_{η}, where 0.08≤η≤0.14; SmFeAsO_{1-θ}F_{θ}, where 0≤θ≤0.35; PrFeAsO_{1-ι}F_{ι}, where 0≤ι≤0.225; CeOFe_{1-κ}Zn_{κ}As, where 0≤κ≤0.2; CaAlOFeAs; CaCuO₂; LaSrNiO; NdCaNiO; PrCaNiO; and Tl₂Ba₂Ca₂Cu₃O₁₀.

According to a tenth aspect of the present disclosure, a superconducting article comprises a layered structure, the layered structure comprising: a polycrystalline substrate layer; and a metal-doped superconducting layer disposed on the polycrystalline substrate layer, the metal-doped superconducting layer comprising a thickness tₛ greater than or equal to 10 μm and less than or equal to 50 μm, wherein: the metal-doped superconducting layer comprises a first concentration of implanted metal ions; the polycrystalline substrate layer comprises a second concentration of implanted metal ions; and the first concentration of implanted metal ions is greater than the second concentration of implanted metal ions.

An eleventh aspect includes the tenth aspect, wherein the polycrystalline substrate layer is a bulk superconducting material.

According to a twelfth aspect of the present disclosure, a superconducting article comprises a layered structure, the layered structure comprising: a polycrystalline substrate layer; and a metal-doped superconducting layer disposed on the polycrystalline substrate layer, the metal-doped superconducting layer comprising a thickness tₛ greater than or equal to 100 nm and less than 1000 nm, wherein: the metal-doped superconducting layer comprises a first concentration of implanted metal ions; the polycrystalline substrate layer comprises a second concentration of implanted metal ions; and the first concentration of implanted metal ions is greater than the second concentration of implanted metal ions.

A thirteenth aspect includes the twelfth aspect, wherein the metal-doped superconducting layer comprises a thickness tₛ of about 300 nm.

A fourteenth aspect includes any one of the tenth through thirteenth aspects, wherein the polycrystalline substrate layer comprises a ceramic selected from the group consisting of: YBa₂Cu₃O_{7-α}, where 0≤α≤0.65; Pb_{10-β}Cu_{β}(PO₄)O, where 0.9≤β≤1.1; La_{2-γ}Sr_{γ}CuO₄, where 0≤γ≤0.2; La_{2-δ}Ba_{δ}CuO₄, where 0.05≤δ≤0.25; Bi₂Sr₂Ca₂Cu₃O_{10+ε}, where 0≤ε≤0.08; Pb₂Sr₂Y₁Cu₃O_{8+ζ}, where 0≤ζ≤1; LaFeAsO_{1-η}F_{η}, where 0.08≤η≤0.14; SmFeAsO_{1-θ}F_{θ}, where 0≤θ≤0.35; PrFeAsO_{1-ι}F_{ι}, where 0≤ι≤0.225; CeOFe_{1-κ}Zn_{κ}As, where 0≤κ≤0.2; CaAlOFeAs; CaCuO₂; LaSrNiO; NdCaNiO; PrCaNiO; and Tl₂Ba₂Ca₂Cu₃O₁₀.

A fifteenth aspect includes any one of the tenth through fourteenth aspects, wherein the implanted metal ions comprise metal ions selected from the group consisting of copper, iron, nickel, cobalt, molybdenum, and bismuth.

A sixteenth aspect includes any one of the first through fifteenth aspects, wherein the metal doped superconducting layer has a superconducting critical temperature greater than or equal to 293 K.

Additional features and advantages of the embodiments described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1A schematically depicts a polycrystalline substrate with a metal layer deposited thereon as part of a method for making a superconducting article, according to one or more embodiments described herein;

FIG. 1B schematically depicts the focusing of a pulsed laser beam on the metal layer of FIG. 1A as part of a method for making a superconducting article, according to one or more embodiments described herein; and

FIG. 1C schematically depicts a superconducting article formed in accordance with a method for making a superconducting article, according to one or more embodiments described herein.

### DETAILED DESCRIPTION

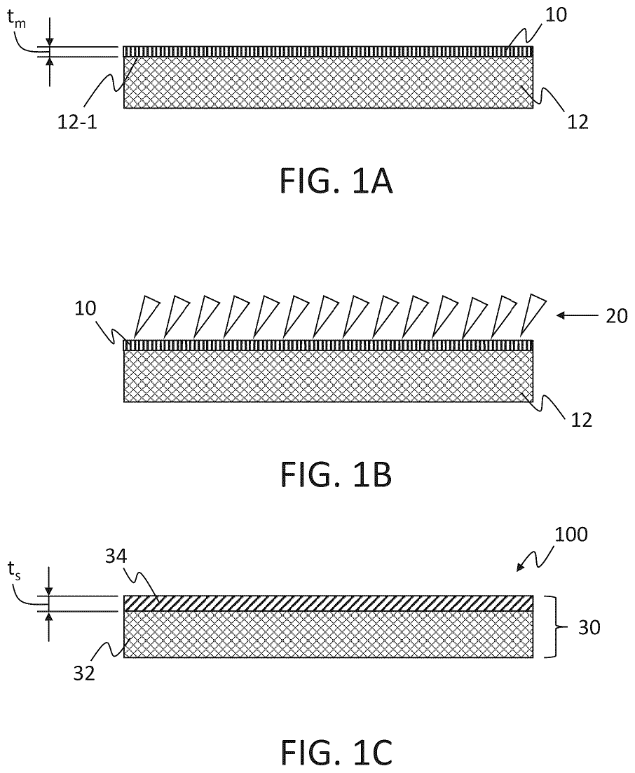

Reference will now be made to methods for making superconducting articles, and superconducting articles made therefrom. One embodiment of a superconducting article comprising a layered structure is schematically depicted in FIG. 1C. The layered structure generally includes a polycrystalline substrate layer and a metal-doped superconducting layer disposed on the polycrystalline substrate layer. In embodiments, the metal-doped superconducting layer may have a thickness tₛ greater than 10 μm and less than or equal to 50 μm. In other embodiments, the metal-doped superconducting layer may have a thickness tₛ greater than or equal to 100 nm and less than 1000 nm. The metal-doped superconducting layer may include a first concentration of implanted metal ions and the polycrystalline substrate layer may include a second concentration of implanted metal ions. The first concentration of implanted metal ions may be greater than the second concentration of implanted metal ions. Various embodiments of methods for making superconducting articles and superconducting articles made therefrom will be described herein with reference to the appended drawings.

Referring now to FIGS. 1A-1C, a method for making a superconducting article 100 comprises depositing a metal layer 10 on a surface 12-1 of a polycrystalline substrate 12 (FIG. 1A) and then focusing a pulsed laser beam 20 on the metal layer 10 to implant metal ions from the metal layer 10 into the polycrystalline substrate 12 (FIG. 1B), thereby forming a layered structure 30 comprising a polycrystalline substrate layer 32 and a metal-doped superconducting layer 34 (FIG. 1C). In embodiments, the metal ions implanted in the metal-doped superconducting layer 34 cause the metal-doped superconducting layer 34 to behave as a superconductor wherein electrical resistance is substantially mitigated and magnetic fields are expelled from the material below a superconducting critical temperature T_{c}. In embodiments wherein the polycrystalline substrate 12 is a bulk superconductor prior to metal ion implantation, the metal ions implanted in the metal-doped superconducting layer 34 increase the superconducting critical temperature T_{c} of the metal-doped superconducting layer 34 relative to the remaining polycrystalline substrate layer 32.

In embodiments, the methods for making a superconducting article described herein may result in the formation of a metal-doped superconducting layer 34 having a thickness tₛ greater than 10 μm and less than or equal to 50 μm, greater than 10 μm and less than or equal to 45 μm, greater than 10 μm and less than or equal to 40 μm, greater than 10 μm and less than or equal to 35 μm, greater than 10 μm and less than or equal to 30 μm, greater than 10 μm and less than or equal to 25 μm, greater than 10 μm and less than or equal to 20 μm, greater than 10 μm and less than or equal to 15 μm, greater than or equal to 12 μm and less than or equal to 50 μm, greater than or equal to 14 μm and less than or equal to 16 μm, greater than or equal to 18 μm and less than or equal to 50 μm, or greater than or equal to 20 μm and less than or equal to 50 μm.

Previous efforts for fabricating thin-film superconductors using pulsed lasers have utilized single crystal substrates in combination with pulsed laser parameters that produce surface superconducting layers having a thickness greater than 1 μm and less than 10 μm. Without wishing to be bound by theory, it is believed that the use of single crystal substrates may affect the diffusion kinetics of metal ions from the metal layer into the substrate in a manner that limits the penetration depth of the implanted metal ions. However, it has now been found that by utilizing a polycrystalline substrate and selecting appropriate parameters for the pulsed laser beam 20, an increased thickness tₛ of the metal-doped superconducting layer 34 may be achieved. In particular, it is believed that metal ions from the metal layer 10 have enhanced diffusivity through the grain boundaries of the polycrystalline substrate 12, and that this enhanced diffusivity contributes to deeper penetration depths of implanted metal ions. Moreover, and again not wishing to be bound by theory, it is believed that increasing the penetration depth of the implanted metal ions, i.e. increasing the thickness tₛ of the metal-doped superconducting layer 34, for example, to greater than 10 μm, may allow for the formation of metal-doped superconducting layers 34 having a crystal structure, a composition, or both, that results in a higher superconducting critical temperature T_{c} than is achievable using conventional fabrication techniques.

In embodiments, the methods for making a superconducting article described herein may result in the formation of a metal-doped superconducting layer 34 having a thickness tₛ greater than or equal to 100 nm and less than 1000 nm, greater than or equal to 100 nm and less than or equal to 950 nm, greater than or equal to 100 nm and less than 900 nm, greater than or equal to 100 nm and less than 850 nm, greater than or equal to 100 nm and less than 800 nm, greater than or equal to 100 nm and less than 750 nm, greater than or equal to 100 nm and less than 700 nm, greater than or equal to 100 nm and less than 650 nm, greater than or equal to 100 nm and less than 600 nm, greater than or equal to 100 nm and less than 550 nm, greater than or equal to 100 nm and less than 500 nm, greater than or equal to 100 nm and less than 450 nm, greater than or equal to 100 nm and less than 400 nm, greater than or equal to 100 nm and less than 350 nm, greater than or equal to 100 nm and less than 300 nm, greater than or equal to 150 nm and less than 500 nm, greater than or equal to 150 nm and less than 450 nm, greater than or equal to 200 nm and less than 450 nm, greater than or equal to 200 nm and less than 400 nm, greater than or equal to 250 nm and less than 400 nm, or greater than or equal to 250 nm and less than 350 nm. In embodiments, the methods for making a superconducting article described herein may result in the formation of a metal-doped superconducting layer 34 having a thickness tₛ of about 300 nm. Without wishing to be bound by theory, it is believed that a thickness tₛ for the metal-doped superconducting layer of about 300 nm may be advantageous for integration in quantum computing systems, semiconductor fabrication processing, and sensing devices.

Previous efforts for fabricating thin-film superconductors utilizing pulsed lasers have used single crystal substrates and implemented a pulse energy of 100 μJ to produce surface superconducting layers having a thickness greater than 1 μm and less than 10 μm. Without wishing to be bound by theory, it is believed that the presence of grain boundaries in the polycrystalline substrate 12 of the methods described herein allows the pulse energy of the pulsed laser beam to be lowered, for example, to a pulse energy greater than or equal to 10 μJ and less than or equal to 40 μJ, such that a thinner metal-doped superconducting layer 34 can be produced that also exhibits high-temperature superconductivity. Moreover, without wishing to be bound by theory, it is believed that, in combination with a pulse energy of greater than or equal to 10 μJ and less than or equal to 40 μJ, other parameters of the pulsed laser beam 20 may be selected along with characteristics of the polycrystalline substrate 12 and the metal layer 10 such that the superconducting properties of the metal-doped superconducting layer 34 can be adjusted as desired for a specific device or application. In other words, it is believed that the methods described herein permit improved fine tuning of the superconducting properties for thin-film superconductors having a thickness tₛ greater than or equal to 100 nm and less than 1000 nm.

In embodiments, the pulsed laser beam 20 may be, for example and without limitation, a diode-pumped solid state laser having a beam power from 0.1 W (watts) to 20 W. In embodiments, the pulsed laser beam 20 is a nanosecond laser beam comprising a beam power of 0.1 W to 5 W. In embodiments, the pulsed laser beam 20 may be a picosecond laser beam comprising a beam power of 5 W to 20 W. In embodiments, the pulsed laser beam 20 may be a femtosecond laser beam comprising a beam power of 1 W to 5 W. Relative to the limited number of controllable parameters of continuous lasers, the pulsed laser beam 20 of the methods described here can be adjusted in several ways to alter the thickness tₛ of the metal doped superconducting layer 34, implanted metal ion concentration of the metal doped superconducting layer 34, and corresponding superconducting properties of the metal-doped superconducting layer 34. As discussed in more detail herein, adjustable parameters of the pulsed laser beam 20 include, but are not limited to, the wavelength, pulse duration, repetition rate, pulse energy, and scan speed. Without wishing to be bound by theory, it is believed that the parameters of the pulsed laser beam 20 may be selected in combination with characteristics of the polycrystalline substrate 12 and the metal layer 10 to achieve higher superconducting critical temperatures T_{c} than are achievable using conventional means for fabricating thin-film superconductors.

In embodiments, the pulsed laser beam 20 may have a wavelength from 266 nm to 1064 nm. In embodiments, the pulsed laser beam 20 may be a nanosecond laser beam comprising wavelength from 266 nm to 532 nm. In embodiments, the pulsed laser beam 20 may be a picosecond laser beam comprising wavelength from 532 nm to 1064 nm. In embodiments, the pulsed laser beam 20 may be a femtosecond laser beam comprising wavelength from 515 nm to 1030 nm. Without wishing to be bound by theory, it is believed that providing the pulsed laser beam 20 with a shorter wavelength may be beneficial for implanting metal ions deeper into the polycrystalline substrate 12, thereby forming a thicker metal-doped superconducting layer 34.

In embodiments, the pulsed laser beam 20 may have a pulse duration greater than or equal to 300 fs (femtoseconds) and less than or equal to 40 ns (nanoseconds). In embodiments, the pulsed laser beam 20 may be a nanosecond laser beam comprising a pulse duration greater than or equal to 10 ns and less than or equal to 40 ns. In embodiments, the pulsed laser beam 20 may be a picosecond laser beam comprising a pulse duration greater than or equal to 5 ps (picoseconds) and less than or equal to 20 ps. In embodiments, the pulsed laser beam 20 may be a femtosecond laser beam comprising a pulse duration greater than or equal to 300 fs and less than or equal to 1000 fs. Without wishing to be bound by theory, it is believed that picosecond lasers and femtosecond lasers may be beneficial for achieving a more consistent implantation location of the metal ions within the crystal structure of the polycrystalline substrate 12.

In embodiments, the pulsed laser beam 20 may have a repetition rate greater than or equal to 10 kHz and less than or equal to 500 kHz, greater than or equal to 10 kHz and less than or equal to 400 kHz, or greater than or equal to 10 kHz and less than or equal to 100 kHz. In embodiments, the pulsed laser beam 20 may be a nanosecond laser beam comprising a repetition rate greater than or equal to 10 kHz and less than or equal to 100 kHz. In embodiments, the pulsed laser beam 20 may be a picosecond laser beam comprising a repetition rate greater than or equal to 100 kHz and less than or equal to 400 kHz. In embodiments, the pulsed laser beam 20 may be a femtosecond laser beam comprising a repetition rate greater than or equal to 100 kHz and less than or equal 400 kHz.

In embodiments, the pulsed laser beam 20 may have a pulse energy greater than or equal to 10 μJ and less than or equal to 40 μJ, or greater than or equal to 10 μJ and less than or equal to 30 μJ. In embodiments, the pulsed laser beam 20 may be a nanosecond laser beam comprising a pulse energy greater than or equal to 10 μJ and less than or equal to 30 μJ. In embodiments, the pulsed laser beam 20 may be a picosecond laser beam comprising a pulse energy greater than or equal to 20 μJ and less than or equal to 40 μJ. In embodiments, the pulsed laser beam 20 may be a femtosecond laser beam comprising a pulse energy greater than or equal to 20 μJ and less than or equal to 40 μJ. Without wishing to be bound by theory, it is believed that picosecond lasers and femtosecond lasers having high peak intensities may be beneficial for implanting metal ions into the polycrystalline substrate on a faster timescale (i.e., more quickly).

In embodiments, the pulsed laser beam 20 may have a scan speed of greater than or equal to 50 mm/s and less than or equal to 3000 mm/s, or greater than or equal to 50 mm/s and less than or equal to 1500 mm/s. The scan speed of the pulsed laser beam 20 may correspond to the rate in which the pulsed laser beam 20 is traversed across the surface of the metal layer 10 (i.e., in units of linear distance per time increment). In embodiments, the pulsed laser beam 20 may be a nanosecond laser beam comprising a scan speed of greater than or equal to 50 mm/s and less than or equal to 1500 mm/s. In embodiments, the pulsed laser beam 20 may be a picosecond laser beam comprising a scan speed of greater than or equal to 500 mm/s and less than or equal to 3000 mm/s. In embodiments, the pulsed laser beam 20 may be a femtosecond laser beam comprising a scan speed of greater than or equal to 500 mm/s and less than or equal to 3000 mm/s. The scan speed may be adjusted to control the concentration of the implanted metal ions in the metal-doped superconducting layer 34. In embodiments, the pulsed laser beam 20 may be parallel to a surface normal of the metal layer 10. Alternatively, the pulsed laser beam 20 may be angled with respect to the surface normal of the metal layer 10, as depicted in FIG. 1B.

In embodiments, the polycrystalline substrate 12 may be, for example and without limitation, a bulk superconducting material. The polycrystalline substrate 12 may comprise a ceramic superconducting material selected from the group consisting of: YBa₂Cu₃O_{7-α}, where 0≤α≤0.65; Pb_{10-β}Cu_{β}(PO₄)O, where 0.9≤β≤1.1; La_{2-γ}Sr_{γ}CuO₄, where 0≤γ≤0.2; La_{2-δ}Ba_{δ}CuO₄, where 0.05≤δ≤0.25; Bi₂Sr₂Ca₂Cu₃O_{10-ε}, where 0≤ε≤0.08; Pb₂Sr₂Y₁Cu₃O_{8+ζ}, where 0≤ζ≤1; LaFeAsO_{1-η}F_{η}, where 0.08≤η≤0.14; SmFeAsO_{1-θ}F_{θ}, where 0≤θ≤0.35; PrFeAsO_{1-ι}F_{ι}, where 0≤ι≤0.225; CeOFe_{1-κ}Zn_{κ}As, where 0≤κ≤0.2; CaAlOFeAs; CaCuO₂; LaSrNiO; NdCaNiO; PrCaNiO; and Tl₂Ba₂Ca₂Cu₃O₁₀. In embodiments, the crystal structure of the polycrystalline substrate 12 may include, but is not limited to, perovskite, orthorhombic, trigonal, and tetragonal crystal structures.

In embodiments, the metal layer 10 may be deposited on a surface 12-1 of the polycrystalline substrate 12 using any suitable deposition method. For example, in embodiments, the metal layer 10 may be deposited via chemical vapor deposition and comprises a thickness tₘ greater than or equal to 2 nm and less than or equal to 3 nm. In embodiments, the metal layer 10 may be deposited via physical vapor deposition and comprises a thickness tₘ greater than or equal to 1 nm and less than or equal to 100 nm. In embodiments, the metal layer 10 may be deposited via chemical solution deposition and comprises a thickness tₘ greater than or equal to 10 nm and less than or equal to 3000 nm.

In embodiments, the metal layer 10 may comprise a metal selected from the group consisting of copper, iron, nickel, cobalt, molybdenum, bismuth, or combinations thereof. In embodiments, more than one species of metal ions may be implanted into the polycrystalline substrate 12 in forming the metal-doped superconducting layer 34. In such embodiments, metal ions of one type may be implanted into the crystal structure at a first location in the crystal structure, and metal ions of a second or third type may be implanted into a second or third location, respectively, in the crystal structure. In embodiments, the parameters of the pulsed laser beam 20 may be selected to produce avalanche ionization to diffuse metal ions from the metal layer 10 into the polycrystalline substrate 12 in forming the metal-doped superconducting layer 34.

The laser-induced implantation of metal ions into the polycrystalline substrate 12 may result in a new crystal structure in the metal-doped superconducting layer 34 relative to the crystal structure of the remaining polycrystalline substrate layer 32. Moreover, the laser-induced implantation of metal ions into the polycrystalline substrate 12 may result in a distorted crystal structure in metal-doped superconducting layer 34 that is otherwise of the same type of crystal structure as that of the polycrystalline substrate 12. The crystalline structure of the polycrystalline substrate 12 and the resulting metal-doped superconducting layer 34 may be characterized using diffraction methods known in the art such as neutron powder diffraction. Without wishing to be bound by theory, it is believed that the parameters of the pulsed laser beam 20 may be selected in combination with characteristics of the polycrystalline substrate 12 and the metal layer 10 such that the resulting metal-doped superconducting layer 34 is substantially free of amorphous phases and contains a reduced number of crystalline defects than is achievable using conventional means for fabricating thin-film superconductors.

The laser-induced implantation of metal ions into the polycrystalline substrate 12 results in a different composition than that of the composition of the polycrystalline substrate 12. The implanted metal ions may replace ions within the crystal structure of the polycrystalline substrate 12. For example, in embodiments wherein the polycrystalline substrate 12 comprises Pb_{10-β}Cu_{β}(PO₄)O, the metal layer 10 may comprise copper, and the methods of making a superconductor article described herein may cause partial replacement of Pb²⁺ ions with Cu²⁺ ions. In other embodiments, the implanted metal ions may be incorporated as interstitial ions into the crystal structure of the polycrystalline substrate 12. For example, in embodiments wherein the polycrystalline substrate 12 comprises YBa₂Cu₃O_{7-α}, the metal layer 10 may comprise copper, and the methods of making a superconductor article described herein may implant Cu²⁺ ions in tetragonally elongated square pyramidal or octahedral environments of the YBa₂Cu₃O_{7-α} polycrystalline substrate 12.

In embodiments wherein the polycrystalline substrate 12 comprises YBa₂Cu₃O_{7-α}, Pb_{10-β}Cu_{β}(PO₄)O, La_{2-δ}Ba_{δ}CuO₄, Bi₂Sr₂Ca₂Cu₃O_{10+ε}, CaCuO₂, or Pb₂Sr₂Y₁Cu₃O_{8+ζ}, the metal layer 10 may comprise copper, and the methods of making a superconductor article described herein may implant Cu²⁺ ions into the polycrystalline substrate 12. In embodiments wherein the polycrystalline substrate 12 comprises PrFeAsO_{1-ι}F_{ι}or CaAlOFeAs, the metal layer 10 may comprise iron, and the methods of making a superconductor article described herein may implant Fe²⁺/Fe³⁺ ions into the polycrystalline substrate 12. In embodiments wherein the polycrystalline substrate 12 comprises LaSrNiO, NdCaNiO, or PrCaNiO, the metal layer 10 may comprise nickel, and the methods of making a superconductor article described herein may implant Ni²⁺ ions into the polycrystalline substrate 12.

As described above, the laser-induced metal ion implantation achieved by the methods described herein makes the doped region of the polycrystalline substrate 12 superconductive or, in embodiments wherein the polycrystalline substrate 12 is a bulk superconductor, increases the superconducting critical temperature T_{c} of the metal-doped superconducting layer 34 relative to the remaining polycrystalline substrate layer 32. In embodiments, the metal-doped superconducting layer 34 formed by the methods described herein has a superconducting critical temperature greater than or equal to 5 K (kelvin), greater than or equal to 10 K, greater than or equal to 20 K, greater than or equal to 30 K, greater than or equal to 40 K, greater than or equal to 50 K, greater than or equal to 60 K, greater than or equal to 70 K, greater than or equal to 77 K, greater than or equal to 80 K, greater than or equal to 90 K, greater than or equal to 100 K, greater than or equal to 110 K, greater than or equal to 120 K, greater than or equal to 130 K, greater than or equal to 140 K, greater than or equal to 150 K, greater than or equal to 160 K, greater than or equal to 170 K, greater than or equal to 180 K, greater than or equal to 190 K, greater than or equal to 200 K, greater than or equal to 210 K, greater than or equal to 220 K, greater than or equal to 230 K, greater than or equal to 240 K, greater than or equal to 250 K, greater than or equal to 260 K, greater than or equal to 270 K, greater than or equal to 280 K, greater than or equal to 290 K, greater than or equal to 293 K, greater than or equal to 300 K, greater than or equal to 350 K, or greater than or equal to 400 K. In embodiments, the metal-doped superconducting layer 34 is stable, i.e., exhibiting substantially zero ion leakage, at temperatures ranging from 10 K to 870 K.

In embodiments, the methods for making a superconducting article described herein may result in the formation of a metal-doped superconducting layer 34 having a first concentration of implanted metal ions and the polycrystalline substrate layer 32 having a second concentration of implanted metal ions. It should be understood that references herein to concentrations of implanted metal ions in a particular layer refer to an average concentration of implanted metal ions in said layer. The first concentration of implanted metal ions in the metal-doped superconducting layer 34 may be greater than the second concentration of implanted metal ions in the polycrystalline substrate layer 32. The concentration of implanted metal ions in the metal-doped superconducting layer 34 and polycrystalline substrate layer 32 may be measured using X-ray photoelectron spectroscopy (XPS) or cross-section scanning electron microscopy in combination with energy dispersive X-ray spectroscopy (SEM-EDS).

In embodiments, the first concentration of implanted metal ions in the metal-doped superconducting layer 34 is greater than or equal to 10⁵ ions/μm³ and less than or equal to 10⁸ ions/μm³. In embodiments, the second concentration of implanted metal ions in the polycrystalline substrate layer 32 is zero.

In embodiments, the methods described herein for making superconducting articles include a heat treatment step that homogenizes the concentration of implanted metal ions in the metal-doped superconducting layer 34. Without wishing to be bound by theory, it is believed that the heat treatment step may achieve a substantially uniform distribution of the implanted metal ions throughout the metal-doped superconducting layer 34. The heat treatment step may include heating the superconducting article 100 to a heat treatment temperature between 700° C. and 1100° C., for example, to heat treatment temperature of about 700° C., about 750° C., about 800° C., about 850° C., about 900° C., about 950° C., about 1000° C., about 1050° C., or about 1100° C. The superconducting article 100 may then be held at this temperature for between 30 minutes and five hours. In embodiments, the heat treatment step includes holding the superconducting article 100 at the heat treatment temperature for a heat treatment time of about 30 minutes, about 40 minutes, about 50 minutes, about 60 minutes, about 1.5 hours, about 2 hours, about 2.5 hours, about 3 hours, about 4 hours, about 4.5 hours, or about 5 hours. The heat treatment temperature and heat treatment time may be selected based on the composition of the polycrystalline substrate 12 and the composition of the metal layer 10. For example, in embodiments wherein the polycrystalline substrate 12 comprises YBa₂Cu₃O_{7-α} and the metal layer 10 comprises copper, the heat treatment temperature may be between 800° C. and 900° C., between 820° C. and 880° C., or about 850° C., and the heat treatment time may be in the range of 30 to 60 minutes, or about 45 minutes.

Ranges can be expressed herein as from “about” one particular value, and/or to “about” another particular value. When such a range is expressed, another embodiment includes from the one particular value and/or to the other particular value. Unless otherwise specified, a range of values, when recited, includes both the upper and lower limits of the range as well as any sub-ranges therebetween. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

As used herein, the indefinite articles “a,” “an,” and the corresponding definite article “the” mean “at least one” or “one or more,” unless otherwise specified. It also is understood that the various features disclosed in the specification and the drawings can be used in any and all combinations.

Reference throughout this specification to “one embodiment,” “embodiments,” “certain embodiments,” “some embodiments,” “various embodiments,” “one or more embodiments,” or “an embodiment” means that a particular feature, structure, material, or characteristic described in connection with the embodiment is included in at least one embodiment of the disclosure. Thus, the appearances of the phrases such as “in embodiments,” “in one or more embodiments,” “in certain embodiments,” “in various embodiments,” “in one embodiment,” “in some embodiments,” or “in an embodiment” in various places throughout this specification are not necessarily referring to the same embodiment. Furthermore, the particular features, structures, materials, or characteristics described in connection with one embodiment may be combined in any suitable manner in one or more other embodiments.

It will be apparent to those skilled in the art that various modifications and variations can be made to the embodiments described herein without departing from the spirit and scope of the claimed subject matter. Thus it is intended that the specification cover the modifications and variations of the various embodiments described herein provided such modification and variations come within the scope of the appended claims and their equivalents.

What is claimed is:

1. A method for making a superconducting article, the method comprising:
depositing a metal layer on a surface of a polycrystalline substrate; and
focusing a pulsed laser beam on the metal layer to implant metal ions from the metal layer into the polycrystalline substrate, thereby forming a layered structure comprising:
a polycrystalline substrate layer; and
a metal-doped superconducting layer comprising a thickness tₛ greater than 10 μm and less than or equal to 50 μm, wherein the metal-doped superconducting layer comprises the metal ions.

2. The method of claim 1, wherein the pulsed laser beam comprises:
a pulse duration greater than or equal to 10 ns and less than or equal to 40 ns;
a wavelength from 266 nm to 532 nm;
a pulse energy greater than or equal to 10 μJ and less than or equal to 30 μJ;
a repetition rate greater than or equal to 10 kHz and less than or equal to 100 kHz; and
a scan speed greater than or equal to 50 mm/s and less than or equal to 1500 mm/s.

3. The method of claim 1, wherein the pulsed laser beam comprises:
a pulse duration greater than or equal to 5 ps and less than or equal to 20 ps;
a wavelength from 532 nm to 1064 nm;
a pulse energy greater than or equal to 20 μJ and less than or equal to 40 μJ;
a repetition rate greater than or equal to 100 kHz and less than or equal to 400 kHz; and
a scan speed greater than or equal to 500 mm/s and less than or equal to 3000 mm/s.

4. The method of claim 1, wherein the pulsed laser beam comprises:
a pulse duration greater than or equal to 300 fs and less than or equal to 1000 fs;
a wavelength from 515 nm to 1030 nm;
a pulse energy greater than or equal to 20 μJ and less than or equal to 40 μJ;
a repetition rate greater than or equal to 100 kHz and less than or equal to 400 kHz; and
a scan speed greater than or equal to 500 mm/s and less than or equal to 3000 mm/s.

5. The method of claim 1, wherein:
the metal layer is deposited via chemical vapor deposition; and
the metal layer comprises a thickness tₘ greater than or equal to 2 nm and less than or equal to 3 nm.

6. The method of claim 1, wherein:
the metal layer is deposited via physical vapor deposition; and
the metal layer comprises a thickness tₘ greater than or equal to 1 nm and less than or equal to 100 nm.

7. The method of claim 1, wherein:
the metal layer is deposited via chemical solution deposition; and
the metal layer comprises a thickness tₘ greater than or equal to 10 nm and less than or equal to 3000 nm.

8. The method of claim 1, wherein the metal layer comprises a metal selected from the group consisting of copper, iron, nickel, cobalt, molybdenum, and bismuth.

9. The method of claim 1, wherein the polycrystalline substrate comprises a ceramic selected from the group consisting of:
YBa₂Cu₃O_{7-α}, where 0≤α≤0.65;
Pb_{10-β}Cu_{β}(PO₄)O, where 0.9≤β≤1.1;
La_{2-γ}Sr_{γ}CuO₄, where 0≤γ≤0.2;
La_{2-δ}Ba_{δ}CuO₄, where 0.05≤δ≤0.25;
Bi₂Sr₂Ca₂Cu₃O_{10+ε}, where 0≤ε≤0.08;
Pb₂Sr₂Y₁Cu₃O_{8+ζ}, where 0≤ζ≤1;
LaFeAsO_{1-η}F_{η}, where 0.08≤η≤0.14;
SmFeAsO_{1-θ}F_{θ}, where 0≤θ≤0.35;
PrFeAsO_{1-ι}F_{ι}, where 0≤ι≤0.225;
CeOFe_{1-κ}Zn_{κ}As, where 0≤κ≤0.2;
CaAlOFeAs;
CaCuO₂;
LaSrNiO;
NdCaNiO;
PrCaNiO; and
Tl₂Ba₂Ca₂Cu₃O₁₀.

10. The method of claim 1, wherein the metal-doped superconducting layer has a superconducting critical temperature greater than or equal to 293 K.

11. A superconducting article comprising a layered structure, the layered structure comprising:
a polycrystalline substrate layer; and
a metal-doped superconducting layer disposed on the polycrystalline substrate layer, the metal-doped superconducting layer comprising a thickness tₛ greater than or equal to 10 μm and less than or equal to 50 μm, wherein:
the metal-doped superconducting layer comprises a first concentration of implanted metal ions;
the polycrystalline substrate layer comprises a second concentration of implanted metal ions; and
the first concentration of implanted metal ions is greater than the second concentration of implanted metal ions.

12. The superconducting article of claim 11, wherein the polycrystalline substrate layer is a bulk superconducting material.

13. The superconducting article of claim 11, wherein the polycrystalline substrate layer comprises a ceramic selected from the group consisting of:
YBa₂Cu₃O_{7-α}, where 0≤α≤0.65;
Pb_{10-β}Cu_{β}(PO₄)O, where 0.9≤β≤1.1;
La_{2-γ}Sr_{γ}CuO₄, where 0≤γ≤0.2;
La_{2-δ}Ba_{δ}CuO₄, where 0.05≤δ≤0.25;
Bi₂Sr₂Ca₂Cu₃O_{10+ε}, where 0≤ε≤0.08;
Pb₂Sr₂Y₁Cu₃O_{8+ζ}, where 0≤ζ≤1;
LaFeAsO_{1-η}F_{η}, where 0.08≤η≤0.14;
SmFeAsO_{1-θ}F_{θ}, where 0≤θ≤0.35;
PrFeAsO_{1-ι}F_{ι}, where 0≤ι≤0.225;
CeOFe_{1-κ}Zn_{κ}As, where 0≤κ≤0.2;
CaAlOFeAs;
CaCuO₂;
LaSrNiO;
NdCaNiO;
PrCaNiO; and
Tl₂Ba₂Ca₂Cu₃O₁₀.

14. The superconducting article of claim 11, wherein the implanted metal ions comprise metal ions selected from the group consisting of copper, iron, nickel, cobalt, molybdenum, and bismuth.

15. The superconducting article of claim 11, wherein the metal-doped superconducting layer has a superconducting critical temperature greater than or equal to 293 K.

16. A superconducting article comprising a layered structure, the layered structure comprising:
a polycrystalline substrate layer; and
a metal-doped superconducting layer disposed on the polycrystalline substrate layer, the metal-doped superconducting layer comprising a thickness tₛ greater than or equal to 100 nm and less than 1000 nm, wherein:
the metal-doped superconducting layer comprises a first concentration of implanted metal ions;
the polycrystalline substrate layer comprises a second concentration of implanted metal ions; and
the first concentration of implanted metal ions is greater than the second concentration of implanted metal ions.

17. The superconducting article of claim 16, wherein the metal-doped superconducting layer comprises a thickness tₛ of about 300 nm.

18. The superconducting article of claim 16, wherein the polycrystalline substrate layer comprises a ceramic selected from the group consisting of:
YBa₂Cu₃O_{7-α}, where 0≤α≤0.65;
Pb_{10-β}Cu_{β}(PO₄)O, where 0.9≤β≤1.1;
La_{2-γ}Sr_{γ}CuO₄, where 0≤γ≤0.2;
La_{2-δ}Ba_{δ}CuO₄, where 0.05≤δ≤0.25;
Bi₂Sr₂Ca₂Cu₃O_{10+ε}, where 0≤ε≤0.08;
Pb₂Sr₂Y₁Cu₃O_{8+ζ}, where 0≤ζ≤1;
LaFeAsO_{1-η}F_{η}, where 0.08≤η≤0.14;
SmFeAsO_{1-θ}F_{θ}, where 0≤θ≤0.35;
PrFeAsO_{1-ι}F_{ι}, where 0≤ι≤0.225;
CeOFe_{1-κ}Zn_{κ}As, where 0≤κ≤0.2;
CaAlOFeAs;
CaCuO₂;
LaSrNiO;
NdCaNiO;
PrCaNiO; and
Tl₂Ba₂Ca₂Cu₃O₁₀.

19. The superconducting article of claim 16, wherein the implanted metal ions comprise metal ions selected from the group consisting of copper, iron, nickel, cobalt, molybdenum, and bismuth.

20. The superconducting article of claim 16, wherein the metal-doped superconducting layer has a superconducting critical temperature greater than or equal to 293 K.
